(19) United States
(12) Patent Application Publication
(10) Pub. No.: US 2006/0226740 A1
(43) Pub. Date: Oct. 12, 2006

(54) Holding device for holding at least two separate electroacoustic transducers

(76) Inventors: Erich Klein, Himberg (AT); Thomas Pauser, Vienna (AT)

Correspondence Address: PHILIPS INTELLECTUAL PROPERTY & STANDARDS, P.O. BOX 3001, BRIARCLIFF MANOR, NY, 10510, US

(21) Appl. No.: 10/546,944

(22) PCT Filed: Feb. 26, 2004
(86) PCT No.: PCT/IB04/50157

§ 371 Date: Aug. 25, 2005

(30) Foreign Application Priority Data
Feb. 28, 2003 (EP) 03100496.3

(51) Int. Cl. H01L 41/053

(52) U.S. Cl. 310/348

(57) ABSTRACT

A holding device (1) for holding at least two separate electroacoustic transducers (3,4) in an apparatus, which holding device has a retaining configuration (2) common to the at least two transducers (3, 4) with separate transducer accommodation spaces (15, 16) for the at least two transducers (3, 4), constructed as an aid for a joint mounting of the at least two separate tranducers (3, 4) in one apparatus.

The invention relates to an apparatus which comprises at least two separate electroacoustic transducers which are mounted in the apparatus.

The invention further relates to a holding device for holding at least two separate electroacoustic transducers in one apparatus.

It is often necessary in practice to incorporate two or more electroacoustic transducers in a variety of appliances. A typical example of this is formed by mobile telephones, in which often two electroacoustic transducers, preferably electromagnetic or alternatively electrodynamic transducers, are used, one of them being used for the reproduction of speech signals for an ear present in the immediate vicinity, and another one for the reproduction of signals such as ring tones, music signals, and the like in the free range, i.e. at a larger distance of several centimeters from the ears. The former transducers are often denoted earpiece transducers, and the latter transducers are often denoted hands-free transducers. This terminology will be used below for simplicity's sake, but this should not be interpreted as being limitative, because the invention does indeed relate by preference to apparatuses and holding devices provided with such electroacoustic transducers constructed as loudspeakers, but apparatuses and holding devices with other electroacoustic transducers, i.e. with microphones, may equally well be involved.

It is known from the patent document WO 01/17201 A2 for the realization of an earpiece transducer and a hands-free transducer to manufacture each transducer as a separate transducer, i.e. as a single component, at a transducer manufacturer's, whereupon a plurality of transducers is transported in a bulk packaging to a manufacturer of apparatuses, which transducers are then again mounted as individual components in respective apparatuses or in the housings of apparatuses. It is known to supply the two transducers of an apparatus in counterphase for realizing an earpiece transducer and in phase for realizing a hands-free transducer. The known solution thus involves a comparatively large expenditure for the delivery of the transducers and the incorporation of the transducers at an apparatus manufacturer's, which is disadvantageous for the apparatus manufacturer, so that there is a demand for at least reducing this expenditure.

The invention has for its object to provide a remedy for the unfavorable situation sketched above and to provide a solution for the delivery and mounting of at least two transducers in one apparatus or one housing of such an apparatus, such that on the one hand the transducers can be manufactured in a simple and flexible, inexpensive manner, while on the other hand simpler logistics, handling, and mounting are safeguarded in the delivery to an apparatus manufacturer and the mounting at this apparatus manufacturer.

To achieve the above object, inventive features are provided in an apparatus according to the invention such that an apparatus according to the invention can be characterized as follows:

an apparatus comprising at least two separate electroacoustic transducers mounted in said apparatus, wherein the apparatus comprises a holding device provided and constructed for holding the at least two separate electroacoustic transducers, which holding device comprises a retaining means common to the two electroacoustic transducers, which retaining means comprises a separate transducer accommodation space for each transducer, and which holding device is constructed as an auxiliary means for the joint mounting of the at least two separate electroacoustic transducers in the apparatus.

To achieve the above object, furthermore, inventive features are provided in a holding device according to the invention such that a holding device according to the invention can be characterized as follows:

a holding device for holding at least two separate electroacoustic transducers in one apparatus, which holding device comprises a retaining means common to the at least two electroacoustic transducers, which retaining means comprises a separate transducer accommodation space for each transducer, and which holding device is constructed as an auxiliary means for the joint mounting of the at least two separate electroacoustic transducers in the apparatus.

It is advantageously achieved in an apparatus according to the invention and in a holding device according to the invention that several transducers are united into a single module or constructional unit by means of the accommodation provided according to the invention, so that it has become simpler to transport the transducers to an appliance manufacturer's, to manipulate the transducers and apply them to a housing or a mounting plate of an apparatus to be manufactured at an apparatus manufacturer's, and to incorporate them in the respective apparatus. A further advantage is that the shape and dimensions of the retaining means may remain substantially the same independently of the dimensions of the transducers, so that no changes are necessary for the apparatus or the housing, even if different requirements are imposed on the properties of the transducers and accordingly the transducers are modified as regards their dimensions. Since individual transducers are to be manufactured at the transducer manufacturer's, the transducers can be favorably manufactured as individual transducers in a mechanized mass production process in large numbers and accordingly against low costs, which transducers are manufactured with different dimensions or diameters and are subsequently inserted into the retaining means, and are subsequently combined into constructional components of uniform external dimensions by these retaining means. All that is required is to provide retaining means with the same external dimensions, but with accommodation spaces of different sizes for the transducers, which retaining means can be manufactured in a simple and inexpensive manner as synthetic resin parts. The fact, furthermore, that the individual transducers can be tested in advance after their manufacture advantageously achieves that only correctly functioning, faultless transducers are accommodated in the holding devices, so that no rejects are to be expected anymore. The transducers may be introduced into the respective accommodation spaces of retaining means, for example by means of clicking or snapping, or in a sliding movement if the accommodation spaces are of a slide-type construction, such that also various techniques for retaining the transducers in one and the same retaining means may be provided. For example, the hands-free transducer may be fixed by means of snap hooks, and the earpiece transducer may be fixed by means of a locking part.

The arrangement of the transducers in the retaining means is advantageously chosen such that the transducers are provided next to one another in the retaining means, such that their transducer axes extend in the same direction or in mutually opposed directions. It is also conceivable to arrange two transducers back-to-back in one retaining means, so that indeed a unit of a greater constructional height is obtained, but with a smaller base surface area. The transducer axes advantageously run mutually parallel, but alternatively they may enclose an angle with one another.

If a closing part is used for fixing the transducer, this closing part may be connected to a base part of the retaining means in a variety of manners. For example, the closing part may be a separate component which is connected to the base part, for example, by thermal deformation or fusion, in particular laser welding, possibly also ultrasonic welding, or alternatively by adhesion. Instead of such connections, alternative connections may be provided, i.e. snap connections or locking connections. It is also possible to provide a forced and interlocking connection, for example by means of rivet-type pins or pegs of synthetic resin whose ends are thermally deformed. It is in addition advantageous if the closing part is connected to the base part via a hinge, in particular a so-termed film hinge in the case of a synthetic resin construction. The final fixation of the closing part against the base part may be realized by snap elements also in the case of such a hinged joint, or alternatively pegs may be provided which rise, for example, from the base part and onto which the closing part is threaded, such that the pegs enter openings in the closing part.

The accommodation spaces may be substantially closed spaces, but they need not necessarily be of a closed construction. Preferred accommodation spaces are more or less open; this is even necessary partly for rendering possible a passage of sound from or to a transducer membrane. In this respect, for example, a limitation of the accommodation space at the side of the sound passage is formed by merely a ring-shaped wall. It is often favorable, moreover, to fix at least one of the transducers in an accommodation space of a base part or bottom simply by snap connection means, so that neither a ring-shaped wall nor a covering wall is necessary for bounding the accommodation space. Suitably, therefore, a base part or a closing part is provided which is formed with a hook part which grips locally around a transducer and thus retains this transducer in its accommodation space. The hook part may be arranged in the base part at one side of a transducer accommodation space, while opposite thereto the closing part, in an advantageous embodiment, associated with an adjoining transducer accommodation space for fixing the transducer held therein may grip over the transducer held in the one accommodation space and thus provide the fixation of this one transducer in addition to the hook part. The overlapping part may furthermore advantageously comprise a positioning element, for example in the form of an opening, such that the transducer enters this opening with a projection and can thus be immovably retained to the base part by means of this overlapping part and the hook part mentioned above.

An assembly consisting of the retaining means and the transducers mounted therein may be retained in an apparatus in that the retaining means is provided with a double-sided adhesive foil on the surface of at least one side.

The retaining means furthermore offers the advantageous possibility of simplifying the contacting of the transducers at an optimized location, where a single, common contact region with electrical contact surfaces for the transducers may be provided, such that electrically conducting connection means lead from these electrical contact surfaces to the accommodation spaces for the transducers. The contact region may be provided as a common region in any desired location in the retaining means, according to the manufacturer's wishes, and it is in addition conceivable here to provide one common contact surface (the ground electrode) for all transducers together instead of two contact surfaces for each and every transducer, so that the number of contact surfaces is reduced from four to three in the case of two transducers. The contact surfaces may highly advantageously be provided on the outside of the closing part mentioned above if this closing part is arranged opposite the open side, where the membrane side of the transducer is present, and may thus have a sufficiently large surface area. It is alternatively possible, however, to accommodate the contact surfaces on the base part in a common contact region.

The invention will now be explained in more detail with reference to preferred embodiments, to which it is by no means limited, and with reference to the accompanying drawings.

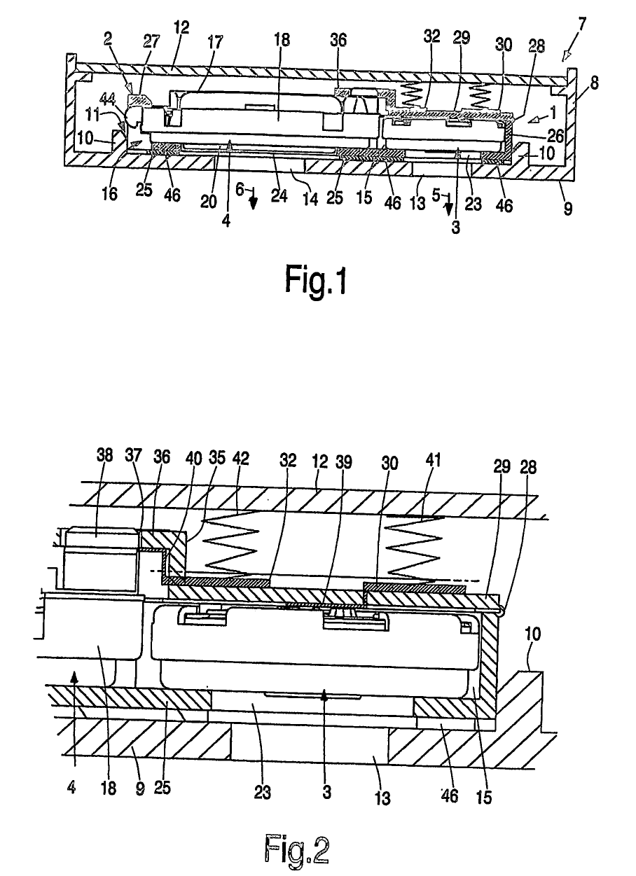

FIG. 1 is a longitudinal sectional view substantially taken on the line I-I in FIG. 3 of a retaining means according to the invention, which retaining means accommodates two electroacoustic transducers and is depicted in a housing that is diagrammatically shown in cross-section, which housing forms part of an apparatus, in particular of a mobile telephone.

FIG. 2 shows in a manner similar to that of FIG. 1, but on a larger scale for greater clarity, the contact surfaces and electrical connections of the retaining means of FIG. 1.

FIG. 3 is a plan view of the retaining means with the transducers of FIG. 1, but without housing.

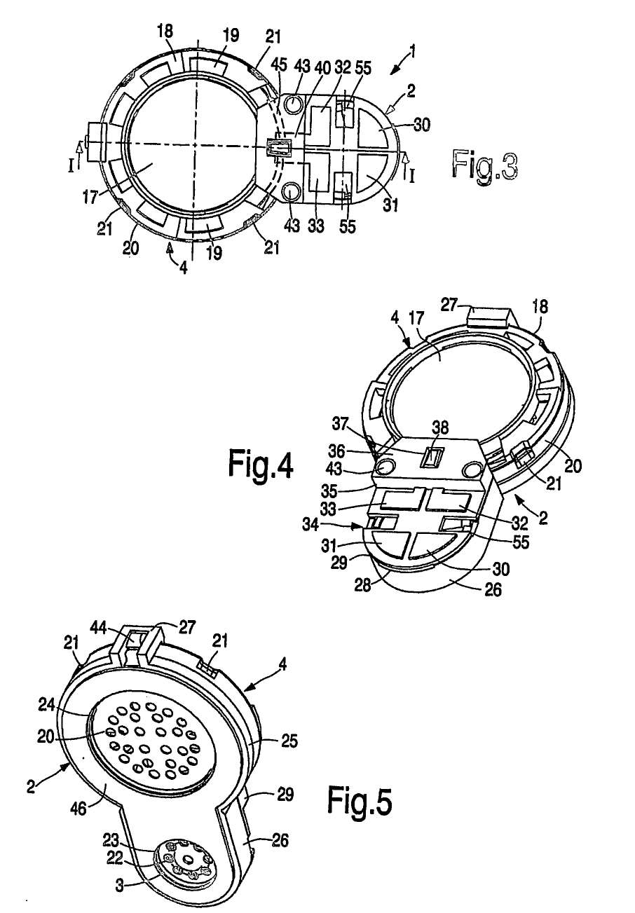

FIG. 4 is an axonometric view of the retaining means of FIGS. 1 to 3 with the two transducers inserted therein.

FIG. 5 is a perspective view of the retaining means with transducers as in FIGS. 1 to 4, but viewed from a different point compared with FIG. 4.

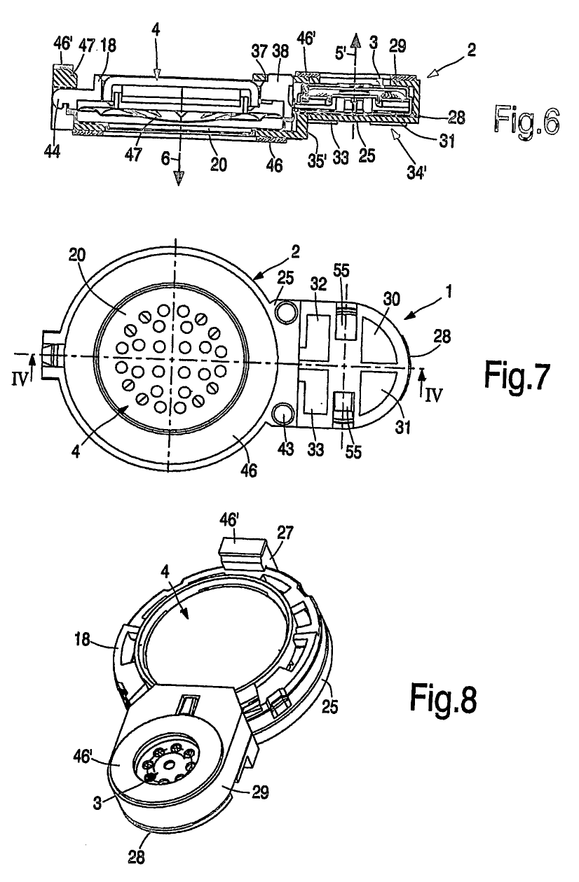

FIG. 6 shows in a manner similar to that of FIG. 1 a modified retaining means with two transducers inserted therein, without housing, in a longitudinal sectional view taken on the line VI-VI in FIG. 7, wherein in contrast to the embodiment of FIGS. 1 to 5 the transducer axes of the two transducers extend in mutually opposed directions, so that the two transducers have mutually opposed sound projection directions.

FIG. 7 is a bottom view of the retaining means with transducers of FIG. 6.

FIG. 8 is a perspective view of the retaining means with transducers of FIGS. 6 and 7, viewed from the upper side of the retaining means.

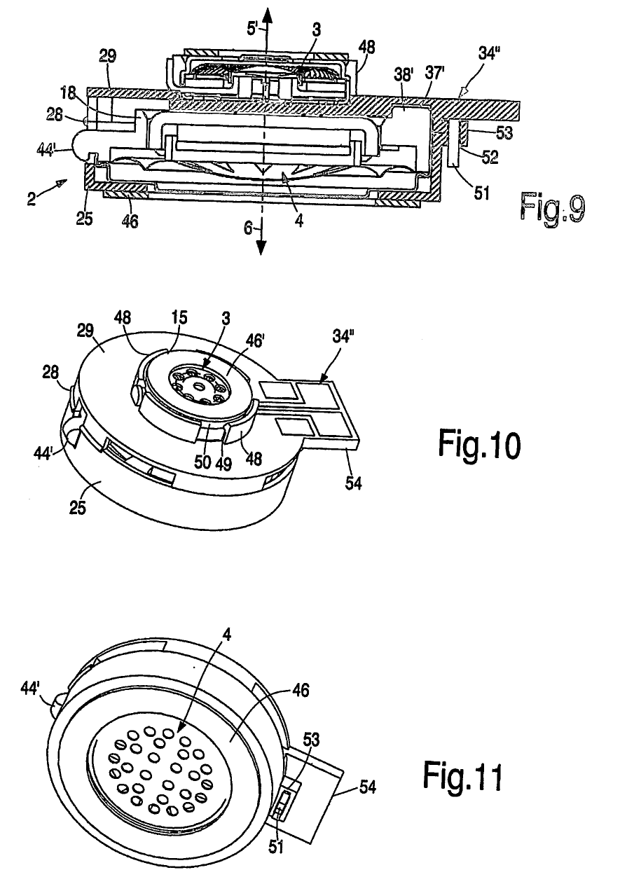

FIG. 9 is a longitudinal sectional view of yet another retaining means, in which two transducers are arranged back-to-back.

FIGS. 10 and 11 are perspective views of the retaining means of FIG. 9 viewed from below and above, respectively.

The first embodiment of the holding device 1 according to the invention shown in FIGS. 1 to 5 essentially consists of a retaining means 2 for two electroacoustic transducers 3, 4 in the form of small loudspeaker enclosures, which two transducers 3, 4 in this case have a diameter of approximately 13 mm and in the mounted state project sound in the same direction—see the arrows 5 and 6 in FIG. 1 —, i.e. the transducer axes of the two transducers 3, 4 run in the same direction. As is shown in FIGS. 1 and 2, the retaining means 2 is incorporated together with the two transducers 3, 4 in a housing 7 so as to form part of an apparatus that is not shown in any detail, i.e. in particular a mobile telephone. The housing 7 here has a holder part 8 with a bottom 9 from which projections 10 rise at given mutual distances so as to provide a seat 11 for the retaining means 2. At its upper side, the holder part 8 of the housing 7 is closed by a lid 12. The bottom 9 of the holder part 8 of the housing 7 has two sound emission openings 13, 14 for the two transducers 3, 4. Synthetic fabrics may be provided in front of the transducers 3, 4 (not shown in the drawing) inside these sound emission openings 13, 14 in a conventional manner, if so desired.

The transducers 3, 4 may be, for example, a so-termed earpiece transducer 3 and a hands-free transducer 4, said earpiece transducer 3 being active in operation against the ear, whereas the hands-free transducer 4 is also operational at a clear distance from the ears, in particular for emitting call signals in the open space. Each of these transducers 3, 4 has its own respective accommodation space 15, 16 in the retaining means 2. Each transducer 3, 4 has a synthetic resin ring, for example referenced 18, surrounding in conventional manner its own cavity, for example referenced 17 (see FIG. 1), as a mounting aid, as is most clearly visible in FIGS. 3 and 4. The synthetic resin ring 18 may be provided with air vents 19 as shown in FIGS. 3 and 4 so as to vent the rear side of a membrane that is situated at the opposite side within a perforated metal cover and which is not visible in detail in FIGS. 1 to 5. Furthermore, FIGS. 3, 4, and 5 show embossed parts 21 of a perforated metal cover 20 provided in depressions at the circumference of the synthetic resin ring 18, which embossed parts 21 serve to achieve a compact assembly consisting of the transducer proper, for example 4, and the associated synthetic resin ring 18. As is visible in particular from FIG. 4, furthermore, the other, for example smaller transducer 3 has a perforated metal cover 22 which is visible through the sound emission opening 13 in the bottom 9 of the holder part 8 of the housing as well as through an aligned opening 23 in the retaining means 2. In a similar manner, an aligned opening 24 is also provided in the retaining means 2 for the hands-free transducer 4 so as to be in alignment with the sound emission opening 14 in the housing bottom 9.

These two openings 23, 24 are provided in a base part 25 of the retaining means 2, as is seen in FIGS. 1 to 5, which base part 25 is substantially planar, while an upright wall 26 is provided at one side, i.e. in the region of the accommodation space 15 for the earpiece transducer 3, which wall extends semi-circularly, diametrically opposite a hook part 27 associated with the accommodation space 16 for the hands-free transducer 4, with linear extension limbs. An upper, substantially planar closing part 29 is connected to this upright wall 26 via a joint 28, said part supporting, for example, four contact surfaces 30, 31 (for the earpiece transducer 3) and 32, 33 (for the hands-free transducer 4). An overlapping part 36 connects to the contact region 34 thus formed with the contact surfaces 30 to 33 via a step 35, as is visible from FIGS. 1 and 2 and best of all from FIG. 4, which overlapping part grips over the accommodation space 16 for the hands-free transducer 4 in the region opposite the hook part 27 so as to fix the hands-free transducer 4 in the accommodation space 16. Additionally, the overlapping part 36 has an opening provided as a positioning element 37 with which a positioning lug provided as a mating positioning element 38 at the transducer 4, more exactly at its synthetic resin ring 18, engages in the assembled state, as is visible in particular from FIGS. 2 and 4.

As is furthermore apparent, for example from FIG. 2, electrically conducting connection means 39, 40 extend from the contact surfaces, for example 30, 32, through the closing part 29 into the accommodation spaces 15, 16 for the two transducers 3, 4 so as to achieve electrical connections to the connection pads of these transducers 3,4 (not shown in any detail). The contact surfaces, for example 30, 32 (see FIG. 2), in their turn are contacted by contact springs 41,42 which bear with their remote ends on the inside of the cover 12 of the housing 7 and are connected there to electrical connection lines for connection to the remaining circuitry, which is not of interest here, in a conventional manner not shown in detail in the drawing. The contact springs 41, 42 additionally also serve to keep the retaining means 2, which forms an aid for the joint assembly of the two transducers 3, 4, pressed down in its seat 11 in the housing 7, irrespective of the possibility that the base part 25 of the retaining means 2 may be held in this seat in a tight fit between the projections 10.

The retaining means 2, i.e. the base part 25 and the closing part 29, consists preferably of an integral synthetic resin part, the joint 28 being formed by a so-termed film hinge, cf. in particular FIG. 2. It is conceivable in principle to provide a conventional hinge or the like as the joint 28. The joint 28 may also be absent, i.e. the closing part 29 in this case is a component manufactured separately from the base part 25. If these parts 25, 29 are made from synthetic resin, the closing part 29 may be fixed to the base part 25 by thermal fusion (laser welding, ultrasonic welding) or by adhesion in the assembled state of the two transducers 3, 4, or alternatively, for example, by means of pins or pegs 43 (cf. FIG. 4) rising from the base part 25. It is also advantageous in this case to deform the ends of the pins 43 visible in FIG. 4 thermally so as to obtain not only a force-actuated seat of the closing part 29 on the pins 43, but in addition also an interlocking closure by means of a rivet-type construction.

The pins 43 are also advantageous if the joint 28 is present, as shown, so as to keep the closing part 29 in the closed position as shown. If no joint 28 is provided, a comparable third pin (possibly of a smaller diameter) may be provided in the region adjacent to the edge where the joint 28 is shown in FIG. 4, so as to obtain a total of three pins for fixing the closing part 29 to the base part 25—more accurately to the upright wall 26 thereof.

Mounting of the two transducers 3, 4 in the retaining means 2 in the embodiment shown in FIGS. 1 to 5 is performed such that the closing part 29 is hinged up about the joint 28, whereupon the transducer 3, i.e. the earpiece transducer, is centered and inserted such that its perforated metal cover 22 is visible through the opening 23, and then the other transducer 4, i.e. the hands-free transducer, is inserted such that its synthetic ring 18 is laid with a projection 44 (see FIG. 1) below the hook part 27. Then the transducer 4 with its projecting positioning element 38 is exactly aligned with the opening provided as a mating positioning element 37 in the overlapping part 36 of the closing part 29, and the closing part 29 is hinged down into its operational position as shown in FIGS. 1 and 2, whereby it is passed with openings (not shown) in the overlapping part 36 over the pins 43 (see FIG. 4). The seat of each pin 43 in the respective opening in the overlapping part 36 has a narrow fit, so that any further processing is unnecessary, because also the film hinge provided as the joint 28 provides a bias tension to keep the closing part 36 in the closed position. It is conceivable, however, to deform the ends of the pins 43 thermally, as was noted above, or to provide a thermal fusion so as to obtain a fixed connection of the closing part 29 to the upright wall 26 of the base part 25.

The broken lines in FIG. 3 serve to indicate diagrammatically that the electrically conducting connection means 40 leading from the contact surfaces 32, 33 to the accommodation space 16 for the transducer 4 are connected to the transducer connection terminals via resilient contact brackets 45.

It is visible from FIG. 1, finally, that the lower side of the base part 25 of the retaining means 2 is covered with a double-sided adhesive foil 46 that keeps only the openings 23, 24 free, which foil serves to glue the retaining means 2 in its seat 11 in the housing 7.

FIGS. 6 to 8 show a second embodiment of the holding device 1 according to the invention, which is different from the one of FIGS. 1 to 5 in that now the two transducers 3, 4 are arranged in the retaining means 2 with mutually opposed sound emission directions, i.e. the transducer axes of the two transducers 3, 4 run in mutually opposed directions (cf. the arrows 5′ and 6 in FIG. 6). In this embodiment, the base part 25 is provided with a step or level difference 35′ (comparable to the step 35 of the closing part 29 in the embodiment of FIGS. 1 to 5), and adjoining thereto a contact region 34′ with the contact surfaces 30, 31, 32, 33 for the electrical connection of the transducers 3, 4 is provided in the region of the transducer 3 (earpiece transducer), i.e. following the same principle as in FIGS. 1 and 2. The closing part 29 now lies with its upper side in one plane with the upper side of the hook part 27 in the representation of FIG. 6. This hook part 27 is provided with a double-sided adhesive foil 46′ for mounting in a matching housing (not shown in FIGS. 6 to 8), as is the closing part 29. In addition, a double-sided adhesive foil 46 may be provided at the lower side of the base part 25 in the region of the transducer 4 (hands-free transducer), so as to obtain an adhesive connection in the housing (not shown) also in this location for fixing the retaining means 2. Furthermore, a film hinge 28 is visible again in FIGS. 6, 7, and 8, so that the closing part 29 can be hinged up for mounting the transducers 3, 4 and can be hinged down again into the operational position shown, and furthermore the transducer 4 is again provided with a synthetic ring 18 with a projection 44 for cooperation with the hook part 27, irrespective of the fact that also the positioning elements 37, 38 are present for the fixation of the transducer 4 to the closing part 29. It is furthermore apparent from FIG. 7 that, in contrast to the embodiment of FIGS. 1 to 5, the pins 53 are provided on the closing part 29 and are accommodated with their ends in openings in the base part 25 when the retaining means 2 is closed.

The embodiment of FIGS. 6 to 8 corresponds to that of FIGS. 1 to 5 in other respects, so that a repetition of the description is unnecessary. Just to be complete, the perforated metal cover 20 of the transducer 4 and the membrane 47 present below it and visible in FIG. 6 are noted here.

FIGS. 9 to 11 show a third embodiment of the holding device 1 according to the invention with a modified retaining means 2, which is designed for a back-to-back mounting of the two transducers 3, 4, with mutually opposed sound projection directions 5′, 6, such that the transducer axes of the two transducers 3, 4 extend in mutually opposed directions. Such an embodiment renders possible a comparatively small base and mounting surface area in an apparatus or in an apparatus housing, but the constructional height is greater because the transducers 3, 4 are arranged one on top of the other. This arrangement may be particularly advantageous in many applications, in particular in mobile telephones with hinging covers, but also in coverless mobile telephones. The embodiments of FIGS. 1 to 5 and FIGS. 6 to 8 are particularly suitable for incorporation in flat hinging covers of mobile telephones.

The retaining means 2 of FIGS. 9 to 11 also has a base part 25 and a closing part 29 connected thereto via a joint 28, again a film hinge, such that this closing part 29 is again substantially planar, but it does contain a compartment formed by curved wall segments 48 (see FIG. 10) as an accommodation space 15 for the transducer 3 (earpiece transducer). The wall segments 48 may grip with hooked edges as hook parts 49 over shoulders 50 of the transducer 3 so as to act as snap closures, thus keeping the transducer 3 fixed in its accommodation space 15. The closing part 29 fisher supports hook-shaped snap elements 51 shown in FIGS. 9 and 11 which pass through an opening 52 in a block 53 formed integrally with the base part 25 and grip behind this when the base part 25 and the closing part 29 are hinged towards one another. The closing part 29 has a planar contact region extension 54 from which the snap elements 51 project on the side facing the base part, whereas on the opposite side again a common contact region 34″ with contact surfaces is provided (visible in particular in FIG. 10, but not shown in detail for simplicity's sake). FIGS. 9 and 10 further show that the transducer 4 (hands-free transducer) passes with a projection 44′ provided on its synthetic resin ring 18 through an opening in the base part 25, said projection being comparable to the projection 44 in the embodiments of FIGS. 1 to 5 and 6 to 8, thus locking the transducer against rotation. In addition, the closing part 29 again has a positioning element, i.e. in the form of a locking depression 37′ (see FIG. 9) for cooperation with a projecting positioning element 38′ on the synthetic resin ring 18 of the transducer 4.

Finally, double-sided adhesive foils or adhesive tapes 46, 46′ for retention in an apparatus housing are provided on both sides, i.e. on the bottom surface of the base part 25 and on the metal cover of the earpiece transducer 3.

The two electroacoustic transducers 3, 4 are united mechanically and electrically into a compact holding device by the retaining means 2, said device forming a transport and assembly unit that can be readily manipulated, i.e. a single component is available for transport and assembly, although two separate transducers 3, 4 were taken from batch production and incorporated. The retaining means 2 here safeguards a good mechanical protection for the two transducers 3, 4 both during transport and during manipulation in the assembly of an apparatus. The transducers 3, 4 may have different diameters and heights, such that only the retaining means 2 must be suitably adapted as regards the dimensioning of its accommodation spaces 15, 16, while the external dimensions of the retaining means 2 remain the same, so that compartment dimensions in an apparatus may be fixed for incorporation in this apparatus. The external dimensions of the retaining means 2 may obviously be readily adapted to the respective constructional conditions in the apparatus in other respects. The mounting of transducers at an apparatus manufacturer's is substantially simplified by such a retaining device, in spite of the fact that mutually separate transducers are provided and can be used. The separate transducers also have the advantage here that they may have different properties as regards the sound volume of the acoustic signals in the case of loudspeakers, as is the case in a mobile telephone with a hands-free transducer (greater sound volume) compared with an earpiece transducer (smaller sound volume). Circuitry measures for an in-phase or counterphase control of transducers may thus become redundant, as described in the cited WO 01/17201 A2.

A wide variety of techniques may be used for retaining the transducers 3, 4 in the retaining means 2, as was noted above, such as in particular interlocking and/or forced connections between parts of the adapter or retaining means 2, in particular the closing part 29 and the base part 25. It is also to be noted that, instead of the four contact surfaces 30 to 33 as shown, only three contact surfaces may suffice (if two transducers 3, 4 are assembled), if a common contact surface or connection electrode (in particular for ground connection) can be provided. The retaining means 2 is not restricted to the geometric shapes shown in the drawings, instead alternative geometric shapes may be provided in dependence on the dimensions of the transducers to be accommodated, such as in the case in which the two transducers are approximately the same size, and the retaining means 2 has an oval shape corresponding to two circles of the same size in plan view. Furthermore, vent openings 55 may be provided in the retaining means 2, as is visible in particular in FIGS. 3 and 4, and also in FIG. 7.

Two transducers 3, 4 constructed as loudspeakers and in addition a transducer constructed as a microphone may be provided in a holding device 1 according to the invention.

1. A holding device for holding at least two separate electroacoustic transducers in one apparatus, which holding device (1) comprises a retaining means (2) common to the at least two electroacoustic transducers (3, 4), which retaining means (2) comprises a separate transducer accommodation space (15, 16) for each transducer (3, 4), and which holding device (1) is constructed as an auxiliary means for the joint mounting of the at least two separate electroacoustic transducers (3, 4) in the apparatus.

2. A holding device (1) as claimed in claim 1, wherein the retaining means (2) is arranged with its transducer accommodation spaces (15, 16) for accommodating the at least two separate electroacoustic transducers (3, 4) side by side.

3. A holding device (1) as claimed in claim 2, wherein the retaining means (2) with its transducer accommodation spaces (15, 16) is constructed for retaining the at least two transducers (3, 4) such that the transducer axes of the at least two transducers extend in mutually opposed directions.

4. A holding device (1) as claimed in claim 2, wherein the retaining means (2) with its transducer accommodation spaces (15, 16) is constructed for retaining the at least two transducers (3, 4) such that the transducer axes of the at least two transducers extend in the same direction.

5. A holding device (1) as claimed in claim 1, wherein the retaining means (2) with its transducer accommodation spaces (15, 16) is constructed for accommodating two transducers (3, 4) back to back.

6. A holding device (1) as claimed in claim 1, wherein the retaining means (2) comprises a base part (25) and at least one closing part (29) designed for connecting to this base part (25).

7. A holding device (1) as claimed in claim 6, wherein the closing part (29) and the base part (25) are made at least partly from thermoplastic synthetic resin, and a thermal fusion is provided for their interconnection.

8. A holding device (1) as claimed in claim 6, wherein at least one of the parts (25, 29) of the retaining means (2) comprises a hook part (27; 49) for locally gripping over one of the transducers (4; 3) accommodated in one of the transducer accommodation spaces (16; 15).

9. A holding device (1) as claimed in claim 1, wherein the retaining means (2) is provided with a double-sided adhesive foil (46, 46′) on at least one side for fixing the retaining means (2) in the apparatus.

10. A holding device (1) as claimed in claim 1, wherein the retaining means (2) has a contact region (34) with electrical contact surfaces (30, 31, 32, 33) from which electrically conducting connection means (39, 40) lead to the transducers.

11. An apparatus, which apparatus comprises at least two separate electroacoustic transducers (3, 4) mounted in said apparatus, wherein the apparatus comprises a holding device (1), which holding device (1) according to claim 1.
